(19) United States
(12) Patent Application Publication
(10) Pub. No.: US 2008/0048784 A1
(43) Pub. Date: Feb. 28, 2008

(54) Medium Voltage or High Voltage Audio Power Amplifier and Protection Circuit

(76) Inventor: Kelvin Shih, Brighton, MI (US)

Correspondence Address: CARLSON, GASKEY & OLDS, P.C., 400 WEST MAPLE ROAD, SUITE 350, BIRMINGHAM, MI, 48009, US

(21) Appl. No.: 11/579,786

(22) PCT Filed: May 18, 2005
(86) PCT No.: PCT/US05/17431

§ 371 Date: Oct. 29, 2007

Related U.S. Application Data
(60) Provisional application No. 60/571,972, filed on May 18, 2004.

(51) Int. Cl. H03F 3/04

(52) U.S. Cl. 330/298

(57) ABSTRACT

A circuit for a power amplifier includes a main amplifier stage having an operational amplifier (110), a buffer NPN transistor (126) and an NPN transistor (127) connected in a totem pole configuration, and a buffer PNP transistor (133) and a PNP transistor connected in a totem pole configuration. The transistors regulate the voltage to the components directly connected to the operational amplifier (110 ). A sampling resistor (137) located between a speaker (140) and an output of the power amplifier measures the current. The sampling resistor (137) is inside a negative feedback loop so that an output resistance will be near zero. A protection circuit includes a high common mode rejection difference amplifier that level shifts the sampling resistor voltage to a ground reference voltage. A precision rectifier full wave rectifies the current signal so that the current signal can he compared to a maximum current. If the instantaneous a circuit for a power amplifier includes a main amplifier stage having an operational amplifier, a buffer NPN transistor and an NPN transistor connected in a totem pole configuration, and a buffer PNP transistor and a PNP transistor connected in a totem pole configuration. The transistors regulate the voltage to the components directly connected to the operational amplifier. A sampling resistor located between a speaker and an output of the power amplifier measures the current. The sampling resistor is inside a negative feedback loop so that an output resistance will be near zero. A protection circuit includes a high common mode rejection difference amplifier that level shifts the sampling resistor voltage to a ground reference voltage. A precision rectifier full wave rectifies the current signal so that the current signal can be compared to a maximum current. If the instantaneous current exceeds the maximum current, the protection circuit turns off both the positive and negative power supplies.

### BACKGROUND OF THE INVENTION

This invention relates generally to a medium voltage or high voltage audio power amplifier and a protection circuit that protects the power amplifier against over current at output terminals.

When the power requirement of an audio power amplifier increases, the current and the voltage of the power amplifier have to be increased. An operational amplifier provides a majority of the gain and the control of the power amplifier. At low voltages, two transistors in common emitter configuration adequately accomplish the level-shifting job. The collector to base junctions of the two transistors have to withstand the full supply voltage when the input signal is small. When the two transistors break down, the operational amplifier and other components will fail, as described in U.S. Pat. No. 4,483,016.

Level shifting circuits are employed to prevent high supply voltage from getting into the operational amplifier. However, the level shifting circuits can stress the collector to base junction of the transistors. If a break down occurs in the transistors, the entire power amplifier will fail. This is the reason that the prior art can only be used to build amplifiers with an output of ±40 volts or 100-watts to an 8 Ohm speaker.

Hence, the present invention provides a medium voltage or high voltage power amplifier and protection circuit that overcomes the drawbacks and shortcomings of the prior art.

### SUMMARY OF THE INVENTION

A circuit for a power amplifier includes a power stage which drives an audio speaker. An input amplifier eliminates a direct current component of a signal before entering a power amplifier stage. The power amplifier stage includes an operational amplifier that provides most of the open loop gain needed for the power amplifier and drives a P channel MOSFET and an N channel MOSFET.

In the present invention, a level-shifting NPN transistor is in series with another NPN transistor to limit the voltage on a collector of the level-shifting NPN transistor. A PNP level-shifting transistor is in series with another PNP transistor to limit the voltage on a collector of the PNP level-shifting transistor. If Zener diodes have a breakdown voltage of 12 volts, the collectors of the NPN and PNP level-shifting transistors will be limited to ±11.3 volts. The totem pole connected transistors and the Zener diodes limit the voltage to all components directly connected to the operational amplifier. The base junction of all the level shifting transistors are not stressed, protecting the operational amplifier from harmful high voltages. The NPN and PNP transistors level shift the output voltage of the operational amplifier from a ground reference voltage to a voltage referenced to either a positive supply or a negative supply. The circuit can be used to build a power amplifier with output voltages over ±100 volts or more, deliver an output current more than ±20 amperes or higher and deliver more than 300-watts to each speaker.

Fuses have a slow operating speed and rarely protect modem high power amplifiers. The present invention also describes a fast and reliable protection circuit that will instantaneously turn off the amplifier when a certain load current is exceeded. The circuit can protect both the power amplifier and the loud speakers.

A sampling resistor located between the speaker and the output of the power amplifier measures the current. Since a negative feedback loop is closed around the sampling resistor, it will not cause any negative effect on the performance of the power amplifier. The sampling resistor is inside the negative feedback loop so that the output resistance of the power amplifier will be zero. A feedback resistor and an input resistor determine the gain of the power amplifier. High open loop gain of the operational amplifier provides the linearity and fidelity to the power amplifier. A complementary common-source MOSFET output stage provides current, voltage and power gain. Combine the two, and a fast, powerful and accurate power amplifier can be easily built.

A protection circuit includes a high-common-mode-rejection difference amplifier that senses current flow through the sampling resistor and converts it to a ground reference voltage. The current signal is then fed to a precision rectifier that converts the alternating current signal to a unidirectional signal. The current signal is compared with a maximum allowed current. If the current signal exceeds the maximum current set point, the protection circuit turns off both the positive and negative power supplies to protect the power amplifier and the speakers.

These and other features of the present invention will be best understood from the following specification and drawings.

### BRIEF DESCRIPTION OF THE DRAWINGS

The various features and advantages of the invention will become apparent to those skilled in the art from the following detailed description of the currently preferred embodiment. The drawing that accompany the detailed description can be briefly described as follows:

FIG. 1 illustrates a circuit for a medium voltage amplifier;

FIG. 2 illustrates a circuit for a high voltage amplifier;

FIG. 3 illustrates a circuit for a high current and high voltage amplifier;

FIG. 4 illustrates a protection circuit using a relay as an output device;

FIG. 5 illustrates a high common mode rejection difference amplifier;

FIG. 6 illustrates a precision rectifier;

FIG. 7 illustrates the protection circuit for two channels; and

FIG. 8 illustrates an output stage for the protection circuit of FIG. 7.

### DETAILED DESCRIPTION OF THE PREFERRED EMBODIMENT

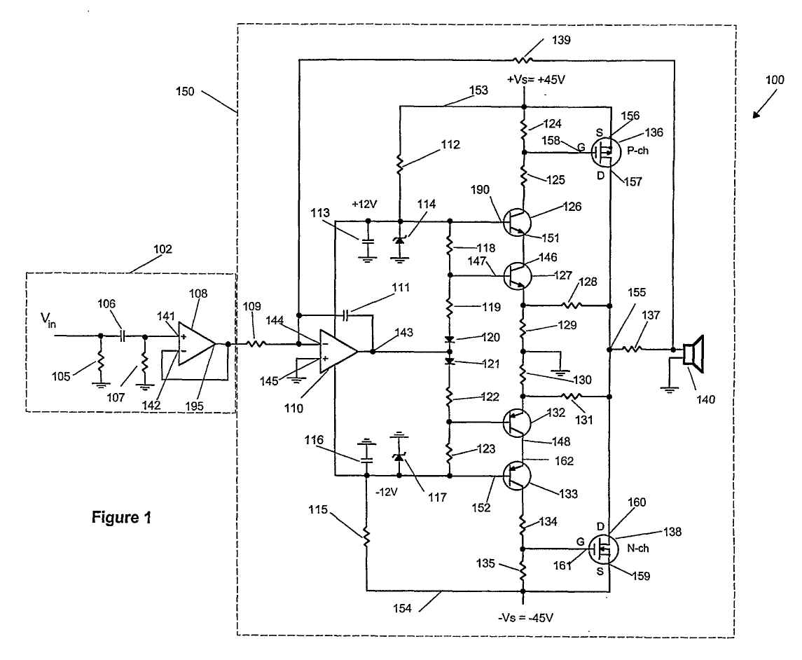

FIG. 1 illustrates a circuit 100 for a medium voltage power amplifier. The circuit 100 includes an output terminal 155, which drives a speaker 140 through a sampling resistor 137. The circuit 100 can be connected to any music source provided the output voltage is compatible to the input of the power amplifier. For example, a computer head phone jack, a portable CD player, a DVD player, a VCD, a MP3 player, or a TV sound output can all be used to drive the power amplifier.

An input amplifier 102 eliminates a direct current component of a music signal before it enters a power amplifier stage 150 and still maintains its low frequency response. An input voltage Vᵢₙ enters a circuit including resistors 105 and 107, a capacitor 106, and an operational amplifier 108. The resistor 105 is the loading resistor of the input voltage Vᵢₙ. The capacitor 106 and the resistor 107 block the direct current component and only allow the alternating current to reach a non-inverting input 141 of the operational amplifier 108. The operational amplifier 108 is connected as a high input resistance voltage follower with an inverting input 142 connected to an output terminal 195.

For example, when the capacitor 106 is 0.47 μF and resistor 107 is 1 MegΩ, the cutoff frequency of the input amplifier 102 can be calculated using the following equation:

$${f}_{cutoff} = \frac{1}{2 π RC} = \frac{1}{2 π ( 1 Meg ) ( 0.47 μF )} = 0.33 Hz$$

This cutoff frequency is much lower than the 20-Hertz human hearing range.

The power amplifier stage 150 is a class AB, full complementary, direct coupled common source amplifier. The power amplifier 150 provides current gain, voltage gain and power gain to drive the speaker 140.

An operational amplifier 110 is a low voltage, low power, high open gain, and high input resistance device. The operational amplifier 110 supplies most of the open loop gain in the system. A driver stage of the power amplifier consists of resistors 118, 119, 122, 123, 124, 125, 128, 129, 130, 131, 134 and 135, diodes 120 and 121, MOSFETs 136 and 138. The voltage gain of the driver stage can also amplify the high frequency response and the slew rate of the operational amplifier 110.

An input resistor 109 and a feedback resistor 139 determine the overall closed loop voltage gain A_{V} of the power amplifier. The overall voltage gain is calculated using the following equation:

$${A}_{V} = - \frac{{R}_{feedback}}{{R}_{in}}$$

R_{feedback} is the feedback resistor 139
Rᵢₙ is the input resistor 109

For example, the circuit 100 uses a positive voltage supply 153 at +45 volts and a negative voltage supply 154 at −45 volts.

The operational amplifier 110 provides most of the open loop gain needed for the power amplifier. The P channel MOSFET 136 and the N channel MOSFET 138 provide the current, voltage and power gain. The larger the open loop gain, the higher the linearity and fidelity when the loop is closed. The speed of the power amplifier mainly depends upon the unity gain bandwidth product and the slew rate of the operational amplifier 110. The driver stage in the power amplifier also has voltage gain up to 30, so it also contributes to the linearity and fidelity. In addition, because the MOSFETs 136 and 138 are much faster devices than bipolar junction transistors, the driver stage has a voltage gain and the overall frequency response of the power amplifier is improved.

The operational amplifier 110 is connected in inverting amplifier configuration with a non-inverting input 145 connected to ground and an inverting input 144 connected to the input resistor 109 and the feedback resistor 139. A capacitor 111 is used between the inverting input 144 and an output 143 as the frequency compensation capacitor. The capacitor 111 usually is a small value capacitor that can prevent the operational amplifier 110 from oscillation. There is no other capacitor in the negative feedback loop of the power amplifier stage.

The operational amplifier 110 has an extremely high input resistance, a very low output resistance and an extremely high open loop gain. All these characteristics with negative feedback can be translated into linearity and fidelity. However, the operational amplifier 110 is a low voltage and a low power device. External devices have to be added to the operational amplifier 110 to build a power amplifier that can deliver more than ±100 volts, more than ±20 amperes, and deliver more than 300-watts of power to the speaker 140. The MOSFETs 136 and 138 and its drive circuit are the external components used to accomplish this.

A resistor 112, a Zener diode 114 and a capacitor 113 are connected as a positive shunt regulator to provide a low positive voltage. A resistor 115, a Zener diode 117 and a capacitor 116 are connected as a negative shunt regulator to provide a low negative voltage. When the Zener diodes 114 and 117 are 1N4742 Zener Diodes, the shunt regulators provide ±12 volts to the operational amplifier 110 and the driver stage of the power amplifier.

The power amplifier stage 150 includes a buffer NPN transistor 126 and a NPN transistor 127 connected in a totem pole, or cascode, configuration and a buffer PNP transistor 133 and a transistor 132 connected in a totem pole, or cascode, configuration. The transistors 126 and 133 regulate the voltage to the components directly connected to the operational amplifier 110. The transistors 127 and 132 level shift the operational amplifier 110 output voltage from a ground reference voltage to a positive supply or a negative supply reference voltage to drive the MOSFETs 136 and 138. The buffer transistors 126 and 133 prevent the collector to base junction of both the transistors 127 and 132 from being subjected to very high supply voltages. The base junctions of the level shifting transistors 127 and 132 are not stressed, thus protecting the operational amplifier 110 from harmful high voltages.

The diodes 120 and 121 mounted on a heat sink provide a 0.7 volt drop to cancel out a base to emitter drop of the transistors 127 and 132. The output 143 of the operational amplifier 110 is connected to a point between the diodes 120 and 121. The diodes 120 and 121 measure the temperature of the heat sink. The forward drop of the diodes 120 and 121 decrease when the temperature increases. This changes the bias circuit and maintains the idle current of the MOSFETs 136 and 138 relatively constant, ensuring the MOSFETs 136 and 138 operate in class AB mode.

The resistors 118, 119, 122 and 123 are connected in series with the diodes 120 and 121 and between the ±12-volt supplies. The value of the resistors 119 and 122 determines the idle current of the power amplifier and the depth of class A biasing.

A base 190 of the buffer transistor 126 is +12 volts, making an emitter 151 of the transistor 126 +11.3 volts because of the 0.7 volt drop. The emitter 151 of the transistor 126 is connected to a collector 146 of the transistor 127, and therefore the collector 146 of the transistor 127 will see a constant voltage of +11.3 volts. Without the buffer transistor 126, the collector 146 of the transistor 127 would be near the positive supply. When the output of the operational amplifier 110 increases, the transistor 127 supplies more emitter current through the resistor 129. When the current through the resistor 129 increases, the current through a resistor 124 also increases proportionally. The voltage drop across the resistor 124 turns on the MOSFET 136 more, causing the output voltage of the power amplifier to go up in the positive direction.

A base 152 of the buffer transistor 133 is −12 volts, making an emitter 162 of the transistor 133 −11.3 volts because of the 0.7 volt drop. The emitter 162 of transistor 133 is connected to a collector 148 of the transistor 132, and therefore the collector 148 of the transistor 132 will see a constant voltage of −11.3 volts. Without the buffer transistor 133, the collector 148 of the transistor 132 would be near the negative supply. When the output of the operational amplifier 110 decreases, the transistor 132 supplies more emitter current through the resistor 130. When the current through the resistor 130 increases, the current through the resistor 135 also increases proportionally. The voltage drop across the resistor 135 turns on the MOSFET 138 more, causing the output voltage of the power amplifier to go down in the negative direction.

In any bipolar junction transistor, the emitter current is nearly the same as the collector current. Therefore, the current in the resistor 129 is nearly equal to the current in the resistor 124, and the current in the resistor 130 is nearly equal to the current in the resistor 135.

The P-channel MOSFET 136 is connected in common source configuration to amplify the positive half cycle. The N-channel MOSFET 138 is connected in common source configuration to amplify the negative half cycle. The sampling resistor 137 is placed between the speaker 140 and the output terminal 155 of the power amplifier to sample the speaker current.

Common source configuration connects sources 156 and 159 of both the P-channel MOSFET 136 and the N-channel MOSFET 138, respectively, to the positive voltage supply 153 and negative voltage supply 154, respectively. Drains 157 and 160 of the P-channel MOSFET 136 and the N-channel MOSFET 138, respectively, are connected together to form the output terminal 155. The gate signal V_{GS} of P-channel MOSFET 136 is supplied by the voltage drop across the resistor 124. The P-channel MOSFET 136 amplifies the positive half cycle of the signal. A gate signal V_{GS} of the N-channel MOSFET 138 is supplied by the voltage drop across the resistor 135. The N-channel MOSFET 138 amplifies the negative half cycle of the signal. The MOSFETs 136 and 138 also includes gates 158 and 161, respectively.

Using the same MOSFETs common source configuration requires much lower positive and negative supply voltages. For example, if the source follower (or common drain configuration) and discrete transistors are used to build a 100 W 8 Ohm amplifier, a ±60 volt supply will be needed instead of the ±45 volt power supply. The MOSFETs 136 and 138 can provide a voltage gain up to 30, amplifying the unity gain bandwidth product and the slew rate of the operational amplifier and providing higher frequency response. A power amplifier with supply voltages over ±100 volts that delivers current more than ±20 amperes and that delivers more than 300-watts of power to the speaker 140 can be built.

The resistors 125 and 134 maintain the gate to source voltages for both the MOSFETs 136 and 138 less then 10 volts. The resistors 128 and 131 provide a small amount of negative feedback to stabilize the output driver stage without introducing poles to the power amplifier. There is no capacitor used in the negative feedback loop of the driver, and therefore the speed of the power amplifier is not impeded.

The sampling resistor 137 located between the speaker 140 and the output terminal 155 of the power amplifier measures the speaker current. The sampling resistor 137 is inside the negative feedback loop so that an output resistance will be zero. Since the feedback loop is closed around the sampling resistor 137, there is no negative effect on the performance of the power amplifier. When the sampling resistor 137 detects a maximum current is exceeded, a protection circuit (described below) turns off both the positive and negative power supplies instantaneously to protect the power amplifier and speakers 140.

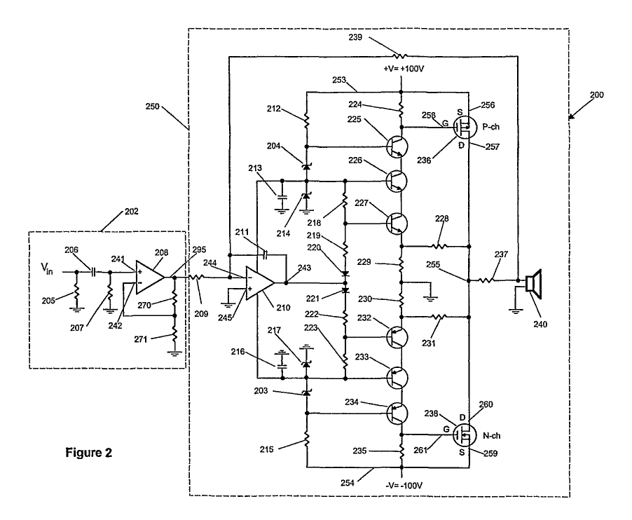

FIG. 2 illustrates a circuit 200 of a high voltage power amplifier. The embodiment of FIG. 2 includes the components of FIG. 1 referenced with numbers 100 greater. In this embodiment, the operational amplifier 208 is connected as a high input resistance non-inverting amplifier. Resistors 270 and 271 determine the gain of this stage. Because the output voltage of the power amplifier is greater than the medium voltage amplifier, this gain is necessary.

The circuit 200 includes a resistor 212, two Zener Diodes 204 and 214 and a capacitor 213 connected as a positive shunt regulator 294 to provide a low positive voltage. A resistor 215, two Zener Diodes 203 and 217 and a capacitor 216 are connected as a negative shunt regulator 293 to provide a low negative voltage. Zener diodes 203 and 204 are high voltage Zener diodes in series that provide an additional voltage drop to keep the operational amplifier 210 safe.

Transistors 227 and 232 are used to level shift the output voltage of the operational amplifier 210 from a ground reference voltage to a voltage referenced to either the positive supply or the negative supply. The circuit also includes additional buffer transistors 225 and 234 instead of the resistors 125 and 134 of FIG. 1.

The buffer transistors 225 and 226 and the Zener diodes 204 and 214 reduce the collector voltage of the transistor 227 in two steps to a safe value. Assuming the Zener diode 214 is 1N4742A (12-volt breakdown) and the Zener diodes 204 is 1N4757A (51-volt breakdown), then an emitter voltage of the transistor 225 or a collector voltage of the transistor 226 can be calculated as follows:
V_{C} of 226=V_{E} of 225=(12V+51V−0.7V)=62.3V

The emitter voltage of the transistor 226 or a collector voltage of the transistor 227 can be calculated as follows:
V_{C} of 227=V_{E} of 226=(12V−0.7V)=11.3V

The buffer transistors 233 and 234 and the Zener diodes 203 and 217 reduce the collector voltage of the transistor 232 in two steps to a safe value. Assuming the Zener diode 217 is 1N4742A (12-volt breakdown) and the Zener diode 203 is 1N4757A (51-volt breakdown), then the emitter voltage of the transistor 234 and the collector voltage of the transistor 233 can be calculated as follows:
V_{C} of 233=V_{E} of 234=(−12V−51V+0.7V)=−62.3V

The emitter voltage of the transistor 233 or the collector voltage of the transistor 232 can be calculated as follows:
V_{C} of 232=V_{E} of 233=(−12V+0.7V)=−11.3V
Using this method, all components directly connected to the operational amplifier 210 will be subject to no more than ±12 volts.

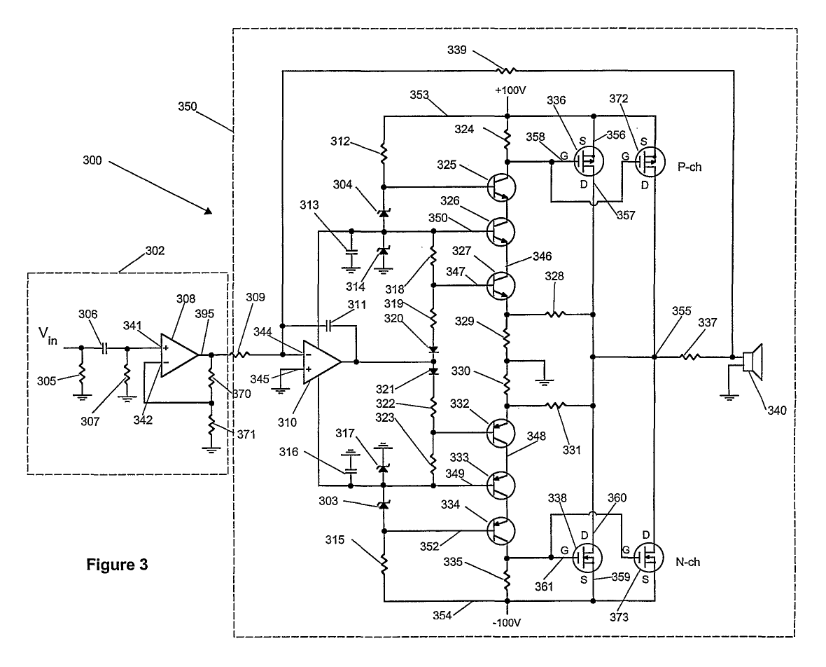

FIG. 3 illustrates a circuit 300 of a high current and high voltage amplifier. The embodiment of FIG. 3 includes the features of FIG. 2 referenced with numbers 100 greater. The circuit 300 further includes an additional P channel MOSFET 372 and an additional N channel MOSFET 373. The P channel MOSFETS 336 and 372 are connected in parallel and in common source configuration to amplify the positive half cycle. The N channel MOSFETs 361 and 373 are connected in parallel and in common source configuration to amplify the negative half cycle. This circuit will be able to deliver to the speaker twice the current than the circuit of FIG. 2.

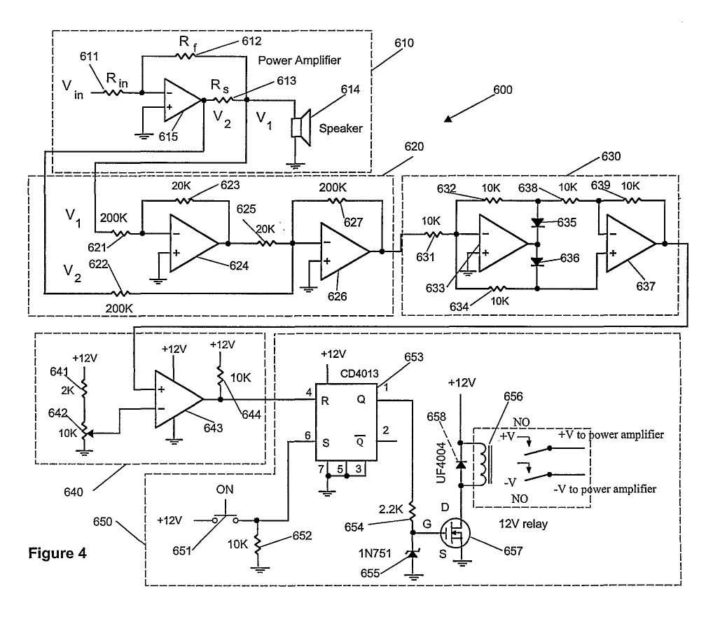

FIG. 4 illustrates a protection circuit 600 used with the circuits of FIGS. 1, 2 and 3 that uses a relay as an output device. A power amplifier system 610 (such as the power amplifier of FIGS. 1, 2 and 3 ) includes a power amplifier 615 that outputs a current through a sampling resistor 613 to a speaker 614. The power amplifier system 610 includes an input resistor 611 and a feedback resistor 612. V₁ and V₂ are the voltages across the sampling resistor 613.

A high common mode rejection difference amplifier 620 measures the difference between V₁ and V₂ and outputs the difference as a ground reference signal. By using the high common mode rejection difference amplifier 620, all the high common voltage disappears. The output of the high common mode rejection difference amplifier 620 is proportional to the current and reference to ground. Two operational amplifiers 624 and 628 with positive and negative supplies are used as inverting amplifiers. The operational amplifier 624 and resistors 621 and 623 form an inverting amplifier with a gain of −1. The operational amplifier 628 and resistors 625, 622 and 627 form an inverting summing amplifier. The output of an operational amplifier 626 is V₁−V₂.

A precision rectifier 630 includes five resistors 631, 632, 634, 638 and 639, two operational amplifiers 633 and 637 and two diodes 635 and 636. The precision rectifier 630 full-wave rectifies the input to a unidirectional signal so a comparison can be made with a direct current set point. The precision rectifier 630 converts the alternating current signal to a unidirectional signal.

A comparator block 640 includes a pull up resistor 644, a resistor 641 and a potentiometer 642 to set the maximum allowable current. The output of the comparator block 640 is fed to a driver 650 that turns the power supply to the power amplifier system 610 off in case the speaker 614 current exceeds the maximum allowed current. The driver 650 includes a momentary switch 651 and a pull down resistor 652 to set a flip-flop 653. The output of the flip-flop 653 is dropped to 5.1 V with a resistor 654 and a 1N751 Zener diode 655. A MOSFET 657 operates as a switch to turn a relay 656 on and off. A diode 658 is a fast recovery diode that acts as a freewheeling diode that eliminates the induced high voltage when the MOSFET 657 turns the relay coil 656 off. When the momentary switch 651 is pushed, the flip-flop 653 is set and the power supply to the power amplifier turns on.

The sampling resistor 613 measures the speaker current. When the peak instantaneous current exceeds an allowable maximum current, the comparator block 640 send a high signal to the driver 650 to turn the power supply off (both positive and negative), protecting both the power amplifier and the speakers 614.

Fuses in all power amplifier circuits are too slow to protect the MOSFETs used in a high power amplifier, which are many times faster than the fuses. A fast over current circuit protects the power amplifier from direct short to ground. The protection circuit 600 works with the peak instantaneous current and not the average current to turn the power supply off. When the protection circuit 600 senses a short or over current, it turns both the positive and negative supply from the power amplifier off.

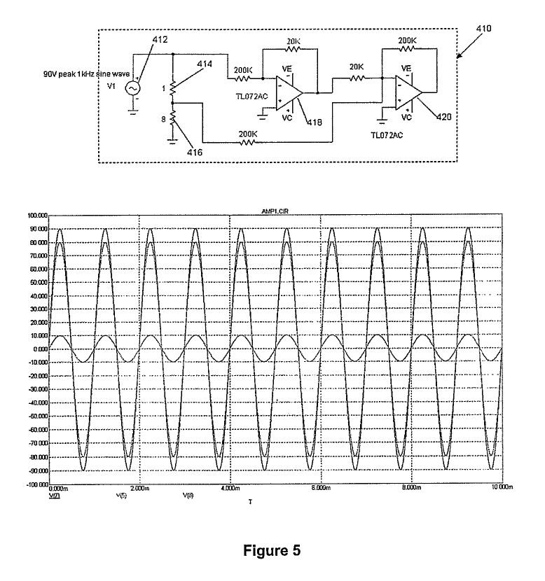

FIG. 5 shows the simulation result of a high common mode rejection difference amplifier 410 done with MicroCap 7 (a simulation program). If the source is a 1 KHz sinusoid 412 that drives a 1Ω sampling resistor 414 in series with an 8Ω speaker 416, the current 10A peak sinusoid current generates a 10-volt sinusoid drop across the sampling resistor. This voltage is referenced to the source, not the ground. By using the high common mode rejection difference amplifier 410, all the high common voltage disappears. The output of the high common mode rejection difference amplifier 410 is proportional to the current and reference to ground. Even if the power supplies for both operational amplifiers 418 and 420 is still ±15 volts, it can measure a voltage difference of two signals that may be several hundred volts.

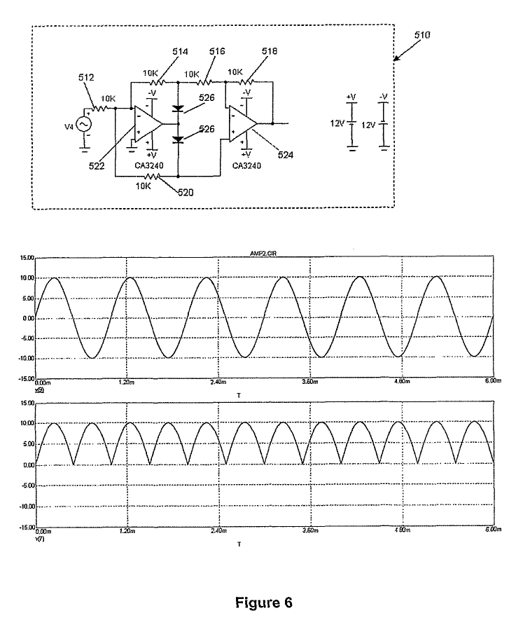

FIG. 6 shows the simulation result of a precision rectifier 510 done with MicroCap 7. Five 10K resistors 512, 514, 516, 518 and 520, two operational amplifiers 522 and 524 and two 1N4148 diodes 526 and 528 form the precision rectifier 516 that can precisely rectify an alternating current voltage to a direct current voltage. A comparator block compares the peak instantaneous current of an alternating current signal to a maximum current setting. If the instantaneous current detected by the sampling resistor 613 exceeds the maximum current setting, a flip-flop reset input is triggered and the power supply to the power amplifier is turned off, protecting both the power amplifier and the speakers 614.

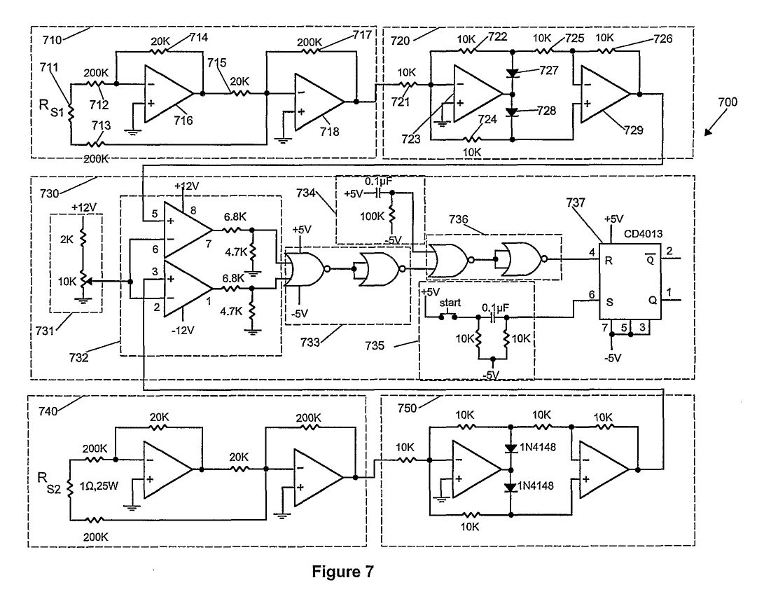

FIG. 7 illustrates a stereo power amplifier 700 including two sampling resistors. A difference amplifier 710 includes resistors 712, 713, 714, 715 and 717 and two operational amplifiers 716 and 718. The difference amplifier 710 turns the sampled current signal, which has very high common mode voltages, to a ground reference signal. A precision rectifier 720 includes resistors 721, 722, 724. 725 and 726, two operational amplifiers 723 and 729 and two diodes 727 and 728. A maximum current setting block 731 sets the maximum current allowed. This voltage is fed to a comparator 732 to compare the setting with both a left and right channel current. The outputs for the left and right channel are fed to an OR gate to turn the power supply off when the maximum current is exceeded by either channel. A start switch 735 turns the power supply on, and power on a reset 734 ensures the power supply is in an off stage when the main switch is first turned on. A flip-flop 737 turns the supply on or off at the same time. The other channel made up by a difference amplifier 740 and a precision rectifier 750 works exactly the same way as the difference amplifier 710 and the precision rectifier 720.

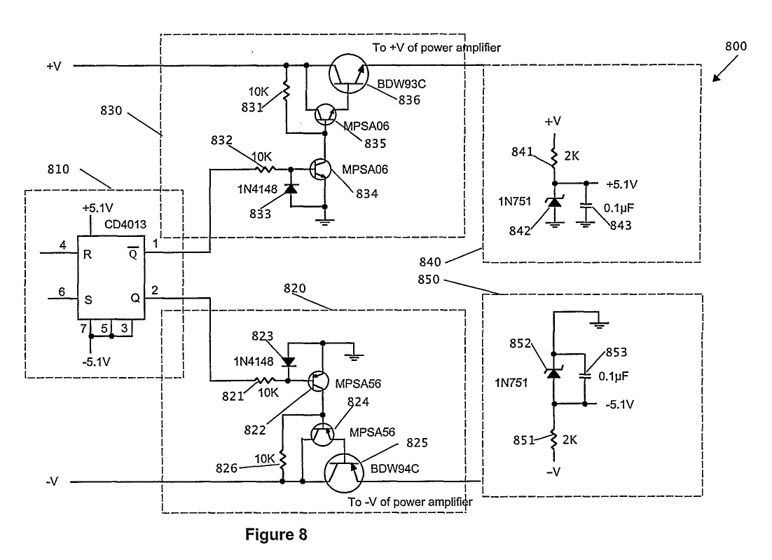

FIG. 8 illustrates an output stage 800 of the protection circuit. A flip-flop 810 is the same as the flip-flop 737 from FIG. 7. A positive supply switch 830 turns the positive side of the supply on and off. A resistor 832 is a current limiting resistor for the base of the transistor 834, and a diode 833 limits the reverse bias voltage to the transistor 834 to −0.7 volts. The transistor 834 controls Darlington connected transistors 835 and 836. The transistor 834 turns off when it receives −5 volts from the flip-flop 810, and the current from positive voltage power supply through the resistor 831 turns the Darlington connected transistors 835 and 836 on. The transistor 834 turns on when it receives a +5 volt signal from the flip-flop 810 and shorts the Darlington transistors 835 and 836 base to ground to turn off the positive supply.

A negative supply switch 820 turns the negative side of the supply on and off. A resistor 821 is the current limiting resistor for the base of the transistor 822. A diode 823 limits the reverse bias voltage to the transistor 822 to −0.7 volts. The transistor 822 controls Darlington connected transistor 824 and 825. The transistor 822 turns off when it receives +5 volts from the flip-flop 810, and the current from a negative voltage power supply through the resistor 826 turns the Darlington transistors 824 and 825 on. The transistor 822 turns on when it receives a −5 volt signal from the flip-flop 810 and shorts the Darlington transistors 824 and 825 base to ground to turn off the negative supply.

A shunt regulator 840 includes a resistor 841, a Zener diode 842 and a capacitor 843 and provides the circuit with +5.1V. A shunt regulator 850 includes a resistor 851, a Zener diode 852 and a capacitor 853 and provides the circuit with −5.1V. The shunt regulators generate the ±5.1 supply voltages for the flip-flop to use.

The foregoing description is only exemplary of the principles of the invention. Many modifications and variations of the present invention are possible in light of the above teachings. The preferred embodiments of this invention have been disclosed, however, so that one of ordinary skill in the art would recognize that certain modifications would come within the scope of this invention. It is, therefore, to be understood that within the scope of the appended claims, the invention may be practiced otherwise than as specifically described. For that reason the following claims should be studied to determine the true scope and content of this invention.

1. A power amplifier comprising:
an operational amplifier;
a level-shifting transistor including a collector to base junction that regulates a voltage to components directly connected to the operational amplifier; and
a buffering transistor that prevents the collector to base junction of the level-shifting transistor from being subjected to high voltages, wherein the level-shifting transistor and the buffering transistor are connected in a cascode configuration.

2. The power amplifier as recited in claim 1 further including a sampling resistor and a main amplifier negative feedback loop defined by a negative input of the operational amplifier and an output of the power amplifier, wherein the sampling resistor is inside the main amplifier negative feedback loop and an output resistance is substantially zero.

3. The power amplifier as recited in claim 1 wherein a capacitor is located in an input amplifier negative feedback loop defined by a negative input of the operational amplifier and an output of the operational amplifier, wherein the capacitor is the only capacitor in the input amplifier negative feedback loop.

4. The power amplifier as recited in claim 2 wherein the sampling resistor detects current.

5. The power amplifier as recited in claim 2 further including a protection circuit, wherein a power supply is turned off when an instantaneous current detected by the sampling resistor exceeds a maximum current.

6. The power amplifier as recited in claim 5 wherein the protection circuit includes a high common mode rejection difference amplifier that level shifts a voltage of the sampling resistor to a ground reference voltage.

7. The power amplifier as recited in claim 5 wherein the protection circuit includes a precision rectifier that full-wave rectifies a current signal from the sampling resistor for comparison with the maximum current.

8. The power amplifier as recited in claim 5 wherein the power supply is a positive power supply and a negative power supply.

9. The power amplifier as recited in claim 1 further including an input amplifier stage and a main amplifier stage, wherein the input amplifier stage eliminates a direct current component of a signal before the signal enters the main amplifier stage.

10. The power amplifier as recited in claim 9 wherein the main amplifier stage includes an input resistor that measures an input current and a feedback resistor that measures a feedback current, and the input resistor and the feedback resistor determine an overall voltage gain.

11. The power amplifier as recited in claim 1 wherein the operational amplifier drives a P channel MOSFET and an N channel MOSFET.

12. A power amplifier comprising:
an operational amplifier;
a level-shifting transistor including a collector to base junction that regulates a voltage to components directly connected to the operational amplifier;
a buffering transistor that prevents the collector to base junction of the level-shifting transistor from being subjected to high voltages, wherein the level-shifting transistor and the buffering transistor are connected in a cascode configuration;
a sampling resistor and a negative feedback loop defined by a negative input of the operational amplifier and an output of the power amplifier, wherein the sampling resistor is inside the negative feedback loop and an output resistance is substantially zero; and
a protection circuit, wherein a power supply is turned off when an instantaneous current detected by the sampling resistor exceeds a maximum current.

13. The power amplifier as recited in claim 12 wherein the protection circuit includes a high common mode rejection difference amplifier that level shifts a voltage of the sampling resistor to a ground reference voltage.

14. The power amplifier as recited in claim 12 wherein the protection circuit includes a precision rectifier that full-wave rectifies a current signal from the sampling resistor for comparison with the maximum current.

15. The power amplifier as recited in claim 12 wherein the power supply is a positive power supply and a negative power supply.
